(19) United States
(12) Patent Application Publication
(10) Pub. No.: US 2005/0230763 A1
(43) Pub. Date: Oct. 20, 2005

(54) Method of manufacturing a microelectronic device with electrode perturbing sill

(75) Inventors: Chien-Chao Huang, Hsin-Chu (TW); Cheng-Kuo Wen, Hsin-Chu (TW); Fu-Liang Yang, Hsin-Chu City (TW)

Correspondence Address: HAYNES AND BOONE, LLP, 901 MAIN STREET, SUITE 3100, DALLAS, TX, 75202, US

(73) Assignee: Taiwan Semiconductor Manufacturing Co., Ltd., Hsin-Chu (TW)

(21) Appl. No.: 10/824,854

(22) Filed: Apr. 15, 2004

(51) Int. Cl. H01L 21/8238; H01L 29/76

(52) U.S. Cl. 257/374; 438/207; 438/218; 257/412

(57) ABSTRACT

A method of manufacturing a microelectronic device. The method includes providing a substrate and forming a patterned feature located over the substrate and a plurality of doped regions. The patterned feature also comprises at least one electrode, wherein the electrode is proximate a plurality of doped layers. The method further includes forming a sill located within the electrode, wherein the sill comprising at least one impurity and adapted for modifying an electrical property of at least one member adjacent the electrode.

### CROSS-REFERENCE

This application is related to the following commonly-assigned U.S. patent application, the entire disclosure of which is hereby incorporated herein by reference: “A Novel Dual Strained CMOS,” Attorney Docket No. 24061.175, filed Apr. 6, 2004 having Chuan-Yi Lin, Wen-Chin Lee, Sun-Jay Chang, and Shien-Yang Wu named as inventors.

### TECHNICAL FIELD

The present disclosure relates generally to microelectronic devices and methods of manufacturing, and more specifically to a microelectronic device with electrode perturbing sill.

### BACKGROUND

An integrated circuit (IC) is formed by creating one or more devices (e.g., circuit components) on a semiconductor substrate using a fabrication process. As fabrication processes and materials improve, semiconductor device geometries have continued to decrease in size since such devices were first introduced several decades ago. For example, current fabrication processes are producing devices having geometry sizes (e.g., the smallest component or line that may be created using the process) of less than 90 nm. However, the reduction in size of device geometries frequently introduces new challenges that need to be overcome.

As microelectronic devices are scaled below 45 nm, the electrical efficiency and become an issue that impacts device performance. Microelectronic device performance can be significantly affected by the electron and hole mobility in semiconductor materials. For example, advanced microelectronic devices may incorporate strained silicon as the substrate. Strained silicon comprises a plurality of layers to provide a lattice mismatch of silicon atoms and other atoms such as germanium. The lattice mismatch can provide enhanced improvement of the electron and/or hole mobility of the microelectronic device, thus a reduction in the threshold voltage may be required for a field effect transistor on strained silicon. However, the plurality of layers that form the strained silicon may not provide optimal device operation for all microelectronic devices of a semiconductor product. For example, NMOS devices and PMOS devices can have differing electrical characteristics when fabricated on strained silicon. Furthermore, the stress in the gate electrode and the channel may vary amongst a plurality of CMOS devices. The differences in the electrical characteristics mandates modification of either the NMOS and/or the PMOS device in strained silicon microelectronic devices.

Accordingly, what is needed in the art is a integrated circuit device and method thereof that addresses the above discussed issues.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1a-b illustrate sectional views of one embodiment of a microelectronic device constructed according to aspects of the present disclosure.

FIG. 2 illustrates a perspective view of one embodiment of a microelectronic device constructed according to aspects of the present disclosure.

FIG. 3 illustrates a sectional view of another embodiment of microelectronic device constructed according to aspects of the present disclosure.

FIG. 4 illustrates a sectional view of one embodiment of an integrated circuit constructed according to aspects of the present disclosure.

FIG. 5 illustrates a sectional view of another embodiment of an integrated circuit device constructed according to aspects of the present disclosure.

### DETAILED DESCRIPTION

The present disclosure relates generally to a microelectronic device and method for fabrication, and more specifically to a microelectronic device with electrode perturbing sill. It is understood, however, that the following disclosure provides many different embodiments or examples. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

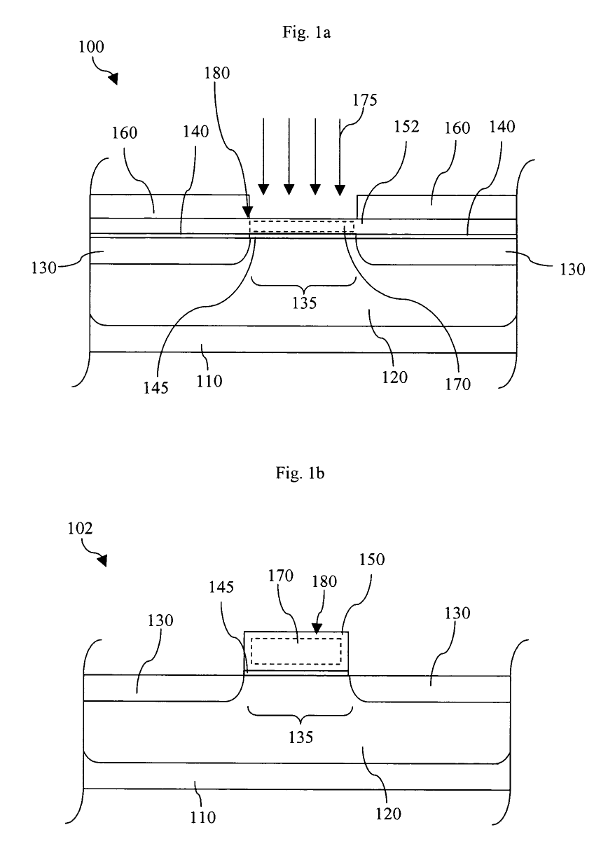

Referring to FIG. 1a, illustrated is a sectional view of one embodiment of a microelectronic device 100 in an intermediate stage of manufacture according to aspects of the present disclosure. Microelectronic device 100 includes a substrate 110, at least one doped region(s) 120, doped source/drain regions 130, a partition layer 140, an electrode insulator 145, an electrode layer 152, a mask 160, and a sill 170.

The substrate 110 may include a plurality of microelectronic devices 100, wherein one or more layers of such a gate structure, or other features contemplated by the microelectronic device 100 within the scope of the present disclosure, may be formed by immersion photolithography, maskless lithography, chemical-vapor deposition (CVD), physical-vapor deposition (PVD), plasma-enhanced chemical vapor deposition (PECVD), atomic layer deposition (ALD) and/or other process techniques. Conventional and/or future-developed lithographic, etching and other processes may be employed to define the microelectronic device 100 from the deposited layer(s). The substrate 110 may be a silicon-on-insulator (SOI) substrate, a polymer-on-silicon, and may comprise silicon, gallium arsenide, gallium nitride, strained silicon, silicon germanium, silicon carbide, carbide, diamond and/or other materials. Alternatively, the substrate 110 may comprise a fully depleted SOI substrate wherein the device active silicon thickness may range between about 200 nm and about 50 nm.

The doped region(s) 120 may be formed in the substrate 110 by ion implantation (although use of a P doped substrate may negate the need for a well region). For example, the doped region(s) 120 may be formed by growing a sacrificial oxide on the substrate 110, opening a pattern for the location of the region(s) 120, and then using a chained-implantation procedure, as is known in the art. It is understood that the substrate 110 may have a P doped well or a combination of P and N wells. The doped region(s) 120, while not limited to any particular dopant types or schemes, in one embodiment, the doped region(s) 120 and/or source/drain regions 130 employ boron as a p-type dopant and deuterium-boron complexes for an n-type dopant. The deuterium-boron complexes may be formed by plasma treatment of boron-doped diamond layers with a deuterium plasma.

In one embodiment, the doped region(s) 120 may be formed using a high density plasma source with a carbon-to-deuterium ratio ranging between about 0.1 percent and about 5 percent in a vacuum process ambient. Boron doping may be provided by the mixing of a boron containing gas with a carbon/hydrogen gas. The boron containing gas may include B₂H₆, B₂D₆ and/or other boron containing gases. The concentration of boron doping may depend upon the amount of boron containing gas that may be leaked or added into the process. The process ambient pressure may range between 0.1 mTorr and about 500 Torr. The substrate 110 may be held at a temperature ranging between 150° C. and about 1100° C. High density plasma may be produced by a microwave electron cyclotron resonance (ECR) plasma, a helicon plasma, a inductively coupled plasma and/or other high density plasma sources. For example, the ECR plasma may utilize microwave powers ranging between about 800 Watts and about 2500 Watts.

As described above, the doped region(s) 120 may also be n-type deuterium-boron complex regions of the substrate 110, which may be formed by treating the above-described boron-doped regions employing a deuterium plasma. For example, selected areas of the substrate 110 may be covered by photoresist or another type of mask such that exposed boron-doped regions may be treated with the deuterium containing plasma. The deuterium ions may provide termination of dangling bonds, thereby transmuting the p-type boron-doped regions into n-type deuterium-boron complex regions. Alternatively, deuterium may be replaced with tritium, hydrogen and/or other hydrogen containing gases. The concentration of the n-type regions may generally be controlled by a direct current (DC) or a radio frequency (RF) bias of the substrate 110. The above-described processes may also be employed to form lightly-doped source/drain regions 130 in the substrate 110. Of course, other conventional and/or future-developed processes may also or alternatively be employed to form the source/drain regions 130.

The partition layer 140 includes a material for providing a process end point and/or for the prevention of formation of the electrode insulator 145 For example, the partition layer 140 may include Si₃N₄, which prevents oxide formation where the prevention layer 140 exits. The partition layer 140 may also include SiON, SiC, and/or other materials adapted for the prevention of material formation during a subsequent process. The electrode insulator 145 or “gate dielectric” may include a SiO₂ and/or nitrided SiO₂. Alternatively, the electrode insulator 145 material may be replaced by the high-k dielectric.

The electrode layer 152 may include a stack of material layers to form the electrode 150. The electrode 150 may provide electrical activation of at least one function of the microelectronic device 100. In one embodiment, the electrode insulator 145 and/or the electrode layer 152 may include multiple layers such as a high-k dielectric later, a polysilicon layer, metal alloy and/or other material layers. Other materials for the electrode 150 may include Ti, Ta, Mo, Co, W, TiN, TaN, WN, MoSi, WSi, CoSi, and/or other materials. In one embodiment, the high-k layer may be formed from a variety of different materials, such as TaN, TiN, Ta₂O₅, HfO₂, ZrO₂, HFSiON, HfSiₓ, HfSiₓN_{y}, HfAlO₂, Al₂O₃, NiSiₓ, or other suitable materials using ALD, CVD, PECVD, evaporation, or other methods. Generally, the high-k layer may have a thickness between approximately 2 and 80 Angstroms. With some materials, such as HfSiON, the high-k layer of the electrode layer 152 may be blanket deposited on the surface of the substrate 110, while other materials may be selectively deposited. Alternatively, it may be desirable to blanket deposit some materials, including HfSiON, in some fabrication processes, while selectively depositing the same materials in other processes. Since the gate oxide thickness continues to decrease along with device geometries, incorporating such high-k materials may yield the higher capacitance needed to reduce the gate leakage associated with smaller device geometries.

The mask 160 includes a pattern material for allowing the formation of the sill 170 at selected portions of the microelectronic device 102. The mask 160 may comprise photo resist, Si₃N₄, SiON, SiO₂, polymer, and/or other materials.

The sill 170 includes a plurality of conducting and/or semiconductor materials which may provide lattice stress balancing amongst a plurality of microelectronic device(s) 100—of an integrated circuit. The sill 170 may be formed upon and/or within the substrate 110. For example, the sill 170 may be deposited upon the substrate 110 by CVD, PECVD, ALD, PVD, and/or other processes. The sill 170 may also be formed by ion implantation as indicated by ion implantation arrows 175, wherein the sill 170 may be formed within an arbitrary depth of the substrate 110. The depth of the ion implantation of sill 170 may be controlled through the impurity implant energy, which may range between about 1 KeV and about 800 KeV. The impurity concentration may range between about 1×10¹³ atoms/cm³ and about 1×10¹⁹ atoms/cm³.

In one embodiment, the ion implantation 175 may be performed by plasma source ion implantation (PSII), or also referred to as plasma source ion immersion. PSII may include a process wherein the electrode layer 152 may be exposed to a plasma source, while an applied bias may be applied to the substrate 110. The processing tool to perform PSII may include a single and/or batch wafer reactor, wherein a direct current (DC) and/or radio frequency (RF) bias may be applied to the substrate(s) 110. The PSII reactor includes a process ambient pressure that may range between 0.01 mTorr and about 1000 Torr. The substrate 110 may be held at a temperature ranging between 150° C. and about 1100° C. High density plasma may be produced by a microwave electron cyclotron resonance (ECR) plasma, a helicon plasma, a inductively coupled plasma and/or other high density plasma sources. The plasma may comprise Ar, H, N, Xe, O, As, B₂H₆, GeH₄, P, and/or other sources of the impurity. For example, the helicon plasma may utilize RF powers ranging between about 200 Watts and about 2500 Watts. The applied bias may range between about ±200 V and about ±5000 V. The application of the bias to the substrate 110 in the plasma creates an extended plasma sheath substantially covering the microelectronic device 100, wherein ions and/or electrons may be accelerated away from the plasma sheath, thereby accelerating the ions of the impurity into the electrode layer 152, to form the sill 170.

The sill 170 may also include a monolayer of the compound. Alternatively, the sill 170 may include a plurality of different impurity layers. For example, the sill 170 may comprise a first Ge layer, a second strained SiGe layer, a layer comprising Si, SiC, and/or other materials.

Of course it is understood that the location of the sill 170 may include a flat plane of the substrate 110, and/or other configurations such as graded, diagonal, and other configurations. The sill 170 may be located within a depth ranging between about 0 and about 50,000 Angstroms as measured from surface 180 determined by a metrology method such as secondary ion mass spectroscopy (SIMS). The sill 170 may have a thickness ranging between about 2 Angstroms and about 250 Angstroms. The sill 170 may include Ge, SiGe, SiC, C, carbide, strained SiGe, and/or other materials.

Referring to FIG. 1b, illustrated is a sectional view of one embodiment of a microelectronic device 102 in an intermediate stage of manufacture according to aspects of the present disclosure. The microelectronic device 102 includes the formed electrode 150 wherein the sill 170 may be located within the region of the electrode 150.

In one embodiment, the substrate 110 may include an air gap to provide insulation for the microelectronic device 100. For example, one structure may comprise a “silicon-on-nothing” (SON), wherein the microelectronic device 100 includes a thin insulation layer including air and/or other insulator. The microelectronic device 100 may include the sill 170 comprising SiGe with a Si cap layer located over the SiGe sill 170. The SiGe sill 170 may be removed in a subsequent step. The Si cap layer may become a device active region for the microelectronic device 100. The Si cap layer may be located over a gap from by the removal of the SiGe sill 140. The gap may comprise air and/or other dielectric material.

In another embodiment, a cap layer or “sill” (not shown) may be located proximate the sill 170. Thus, multiple sill(s) 170 may be incorporated into the electrode 170. For example, one of the multiple sill(s) 170 may include a cap layer. The cap layer may include Si, strained Si, strained SiGe, SiGe, diamond, carbide, and/or other materials. The cap layer may also be located over the sill 170, and may be located proximate the channel region 135. The channel 135 may be formed by a carbon nano-tube. The carbon nano-tube channel 135 may be placed over two electrodes and a heavily doped substrate 110.

Of course, the present disclosure is not limited to applications in which the microelectronic device(s) 100 is a gate structure or a transistor, or other semiconductor device. For example, in one embodiment, the microelectronic device 100 may include an electrically programmable read only memory (EPROM) cell, an electrically erasable programmable read only memory (EEPROM) cell, a static random access memory (SRAM) cell, a dynamic random access memory (DRAM) cell, a single electron transistor (SET), and/or other microelectronic devices (hereafter collectively referred to as microelectronic devices). The geometric features of the microelectronic device 100 may range between about 1300 Angstroms and about 1 Angstroms.

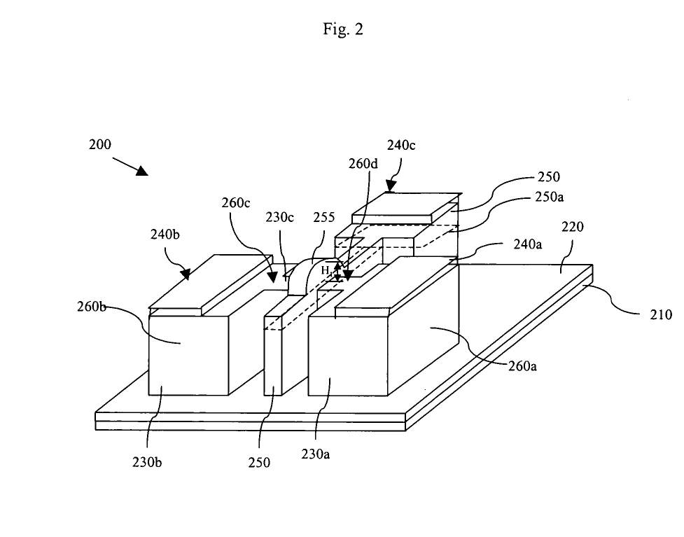

Referring to FIG. 2, illustrated is a perspective view of one embodiment of a microelectronic device 200 constructed according to aspects of the present disclosure. In the illustrated embodiment, the microelectronic device 200 is a FinFET. Of course, aspects of the present disclosure are also applicable and/or readily adaptable to any type of transistor, including single-gate transistors, double-gate transistors, triple-gate transistors, and other multiple-gate transistors, and may be employed in a myriad of applications, including sensor cells, memory cells, logic cells and others.

The microelectronic device 200 includes an insulator 220 formed over or integral to a substrate 210. The microelectronic device 200 also includes first and second semiconductor features 230a, 230b. In one embodiment, the semiconductor features 230a, 230b are source/drain regions. The first and second semiconductor features 230a, 230b are connected by a third semiconductor feature 230c. For example, the third semiconductor feature 230c may be a channel region, possibly having a dopant type opposite a dopant type of the first and second semiconductor features 230a, 230b.

The microelectronic device 200 includes first and second contacts 240a, 240b formed over corresponding ones of the semiconductor features 230a, 230b. The first and second contacts 240a, 240b may include Ti, Ta, Mo, Ni, TiN, TaN, CoSi, TiSi, TaSi, MoSi, NiSi, and/or other conductive materials.

The microelectronic device 200 may also include a biasing feature 250 interposing the first and second semiconductor features 230a, 230b and spanning the third semiconductor feature 230c. In one embodiment, the biasing feature 250 may be a transistor gate. For example, the biasing feature 250 may comprise doped polysilicon and/or other conductive materials such as Ti, Ta, Mo, TiN, TaN, MoSi, NiSi, and CoSi. The biasing feature 250 in the illustrated embodiment extends from at least partially between the first and second semiconductor features 230a, 230b, subsequently widening and terminating at a third contact 240c, which is substantially similar to the first and second contacts 240a, 240b. Moreover, as shown in FIG. 2, the biasing feature 250 may include a boss, wedge, fin or other type of protrusion 255 extending away from the semiconductor features 230a-c. For example, the protrusion 255 may extend to a height H₁ over the semiconductor features 230a-c. The microelectronic device 200 may also include a dielectric layer interposing the biasing feature 250 from one or more of the semiconductor features 230a-c.

The microelectronic device 200 further includes at least one sill 250a. The sill 250a may comprise Ge, SiGe, SiC, carbide, strained SiGe, and/or other materials. The sill 250a may be located within the region of the biasing feature 250. Alternatively, the sill 250a may include a plurality of layers wherein there may be a germanium implant layer followed by a cap layer. The cap layer may comprise Si, SiGe, strained Si, strained SiGe, diamond, carbide, and/or other materials.

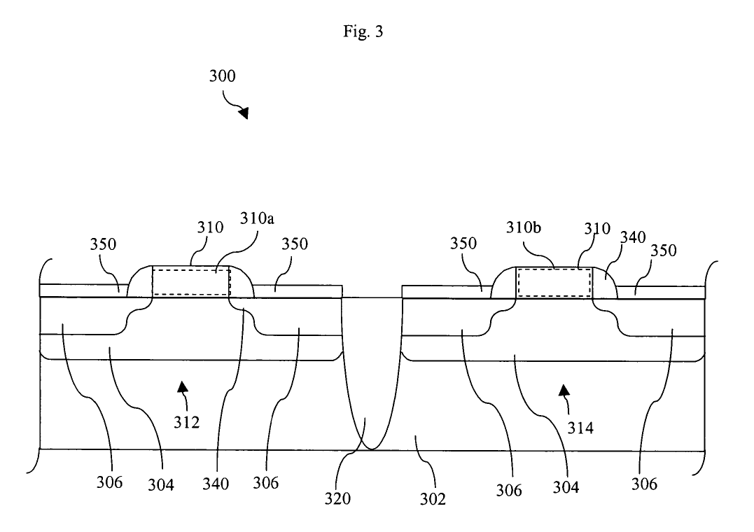

Referring to FIG. 3, illustrated is a sectional view of one embodiment of depth adjustable sill microelectronic device 300 constructed according to aspects of the present disclosure. The microelectronic device 300 includes a substrate 302, an isolation region 320, and at least one microelectronic device(s) 312 and 314.

The isolation region 320 is a region that electrically isolates device(s) 312 and 314. The isolation region 320 may include a trench filled with a dielectric material, such as shallow trench isolation. Alternatively, the isolation region 320 may be formed by an air gap. The isolation region 320 dielectric material may include a low-k dielectric material, and/or may include SiO₂, SiN, SiC, and/or other materials.

The device(s) 312, 314 include PMOS and/or NMOS devices. For example the device 312 may be a PMOS device wherein the sill 310a may be located proximately below the electrode 310. The device 312 may also include the cap layer including Si, SiGe, strained Si, strained SiGe, SiC, diamond, carbide, and/or other materials. The location of the sill 310a proximate the electrode 310 provides for control of the electrode 310 and/or channel stress. The device 314 may be a NMOS device wherein the sill 310b may be located within the electrode 310. The device 314 may also include the cap layer including Si, SiGe, strained Si, strained SiGe, SiC, diamond, carbide, and/or other materials. The device(s) 312, 314 may further include spacers 340 and contacts 350 The spacers 340 may be disposable or non-disposable. The spacers 340 may be formed of SiO₂, SiN, polymer, and/or other materials. The contacts 350 may be formed of CoSi, TiSi, TaSi, MoSi, NiSi, and/or other conductive materials.

In one embodiment, the electrode of the PMOS device 312 may be a different height than the NMOS device 314 For example, the electrode 310 of the NMOS device 314 may be partially etched prior to the formation of the sill 310b. Alternatively, the electrode 310 of the PMOS device 312 may be partially etched prior to the formation of the sill 310a.

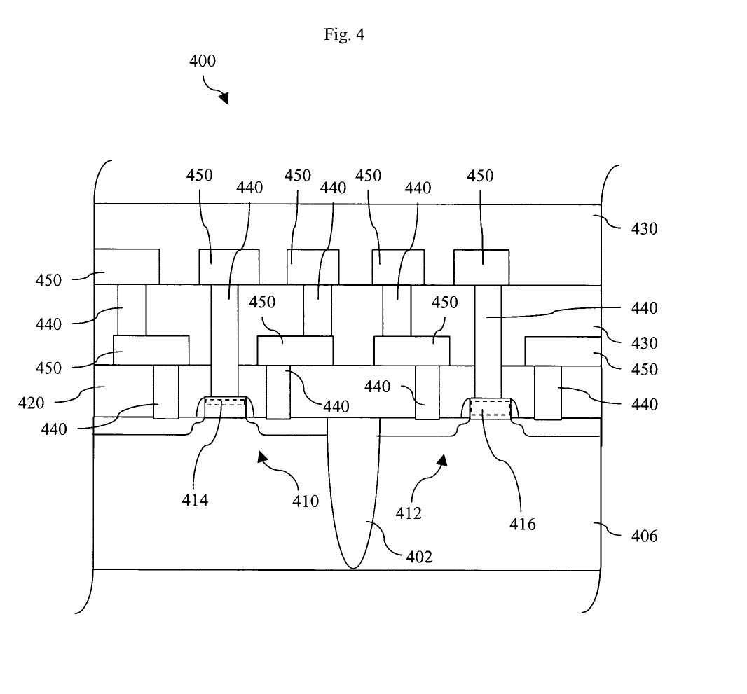

Referring to FIG. 4, illustrated is a sectional view of one embodiment of an integrated circuit device 400 constructed according to aspects of the present disclosure. The integrated circuit device 400 is one environment in which the microelectronic device(s) 102 and/or 300 may be implemented. For example, the integrated circuit device 400 includes a plurality of microelectronic devices 102, 200, and 300 wherein one or more of the microelectronic devices 102, 200, and 300 may be substantially similar.

The integrated circuit device 400 also includes one or more insulating layers 420, 430 located over the microelectronic devices 102. The first insulating layer 420, which may itself comprise multiple insulating layers, may be planarized to provide a substantially planar surface over the plurality of microelectronic devices 102.

The integrated circuit device 400 also includes vertical interconnects 440, such as conventional vias or contacts, and horizontal interconnects 450 (all spatial references herein are for the purpose of example only and are not meant to limit the disclosure). The interconnects 440 may extend through one or more of the insulating layers 420, 430, and the interconnects 450 may extend along one of the insulating layers 420, 430 or a trench formed therein. In one embodiment, one or more of the interconnects 440, 450 may have a dual-damascene structure. The interconnects 440, 450 may be formed by etching or otherwise patterning the insulating layers 420, 430 and subsequently filling the pattern with refractive and/or conductive material, such as tantalum nitride, copper and aluminum.

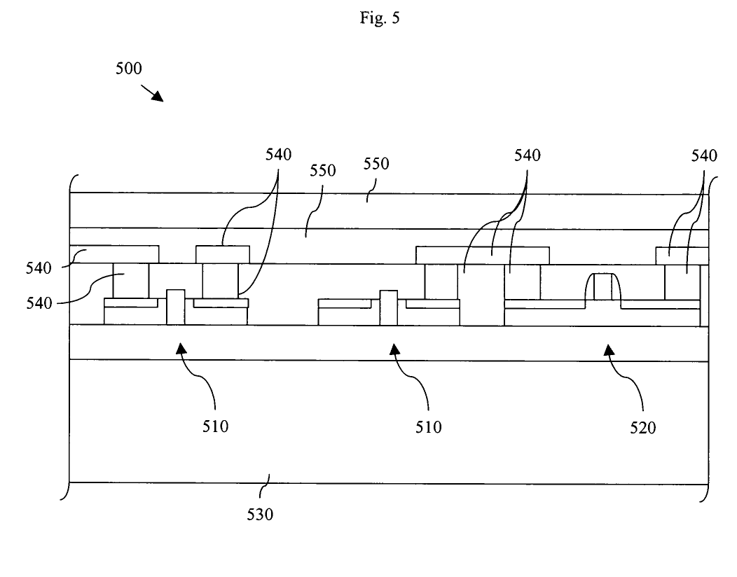

Referring to FIG. 5, illustrated is a sectional view of one embodiment of an integrated circuit device 500 constructed according to aspects of the present disclosure. The integrated circuit device 500 is one environment in which aspects of the above-described microelectronic devices may be implemented. For example, the integrated circuit device 500 includes a plurality of microelectronic devices 510 located on or in a substrate 530, one or more of which is substantially similar to one or more of the microelectronic devices 102, 200, 300 shown in FIGS. 1-3, respectively. The microelectronic devices 510 may be interconnected and/or connected to one or more other microelectronic devices 520 manufactured on or in the substrate 530. The microelectronic devices 520 may be or comprise metal-oxide-semiconductor field-effect-transistor (MOSFET), FinFETs and/or other conventional or future-developed semiconductor devices.

The integrated circuit device 500 also includes interconnects 540 extending along and/or through one or more dielectric layers 550 to ones of the plurality of microelectronic devices 510. The dielectric layers 550 may comprise silicon dioxide, Black Diamonds (a product of Applied Materials of Santa Clara, Calif.) and/or other materials, and may be formed by CVD, ALD, PVD, spin-on coating and/or other processes. The dielectric layers 550 may have a thickness ranging between about 50 Angstroms and about 15,000 Angstroms. The interconnects 540 may include copper, tungsten, gold, aluminum, carbon nano-tubes, carbon fullerenes, a refractory metals and/or other materials, and may be formed by CVD, ALD, PVD and/or other processes.

It is understood, that the present disclosure contemplates the crystalline perturbation of the microelectronic device 100, more specifically, the crystalline perturbation of the electrode 170 and/or a proximate region of a microelectronic structure. The present disclosure may be utilized to provide balancing of electrical characteristics and/or the crystalline stress of a plurality of microelectronic device(s) of integrated circuit 500. For example, predetermined areas of substrate 110 may have openings through mask 160 wherein sill 170 may be located. Therefore, at least one microelectronic device 102, 200, and 300 may have sill 170, while other device(s) 102, 200, and 300 may not have sill 170. Alternatively, the impurity concentration of sill 170 may be different for a plurality of device(s) 102, 200, and 300. Thus, the control of the variation of sill 170 properties provides balancing of electrical properties and/or the crystalline stress of a predetermined population of microelectronic device(s) 102, 200, and 300 of integrated circuit 500.

Although embodiments of the present disclosure have been described in detail, those skilled in the art should understand that they may make various changes, substitutions and alterations herein without departing from the spirit and scope of the present disclosure. Accordingly, all such changes, substitutions and alterations are intended to be included within the scope of the present disclosure as defined in the following claims. In the claims, means-plus-function clauses are intended to cover the structures described herein as performing the recited function and not only structural equivalents, but also equivalent structures.

1. A method of manufacturing a microelectronic device, comprising:
providing a substrate including a plurality of doped regions;
forming a patterned feature located over the substrate, the patterned feature including at least one electrode; and
forming a sill located within the electrode, the sill including at least one monolayer of compound and adapted for modifying an electrical property of at least one member adjacent the electrode.

2. The method of claim 1 wherein the sill is formed prior to the patterning of the electrode.

3. The method of claim 1 wherein the sill is formed in the electrode, the electrode and partially etched to reduce the thickness of the electrode and the sill.

4. The method of claim 1 wherein the sill comprises at least two distinct and segregated impurities.

5. The method of claim 1 wherein the substrate comprises diamond.

6. The method of claim 1 wherein the substrate comprises strained silicon.

7. The method of claim 1 wherein the impurity comprises germanium.

8. The method of claim 1 wherein the electrode impurity concentration ranges between about 1×10¹³ atoms/cm³ and about 1×10¹⁹ atoms/cm³.

9. The method of claim 1 wherein the sill is formed through ion implantation.

10. The method of claim 1 wherein the sill is formed through plasma source ion implantation.

11. The method of claim 1 wherein the sill comprises silicon germanium.

12. The method of claim 1 wherein the sill comprises strained silicon.

13. The method of claim 1 wherein the second sill comprises diamond.

14. The method of claim 1 wherein forming the electrode includes depositing a material selected from the group consisting of:
a metal oxide;
polysilicon; and
metal silicide.

15. The method of claim 1 wherein forming the electrode includes depositing a material selected from the group consisting of:
a metal oxide;
a refractory metal; and
metal silicide.

16. A method of manufacturing a microelectronic device, comprising:
providing a substrate including a plurality of doped regions;
forming a patterned feature located over the substrate, the patterned feature including at least one electrode, wherein the electrode is located over a channel region, the channel region located over an insulator located below the channel region and interposing at least two doped regions, the insulator comprised substantially of air; and
forming a sill located within the electrode, the sill including at least one monolayer of compound and adapted for modifying an electrical property of the channel region adjacent the electrode.

17. A microelectronic device, comprising:
a substrate;
a patterned feature located over the substrate and over a plurality of doped regions, the patterned feature comprising at least one electrode, the electrode being situated proximate a plurality of doped layers; and
a sill located within the electrode, the sill comprising at least one impurity and adapted for modifying an electrical property of at least one member adjacent the electrode.

18. The microelectronic device of claim 17 wherein the sill is formed prior to the patterning of the electrode.

19. The microelectronic device of claim 17 wherein the sill is formed in the electrode, the electrode and partially etched to reduce the thickness of the electrode and the sill.

20. The microelectronic device of claim 17 wherein the sill comprises at least two distinct and segregated impurities.

21. The microelectronic device of claim 17 wherein the substrate comprises diamond.

22. The microelectronic device of claim 17 wherein the substrate comprises strained silicon.

23. The microelectronic device of claim 17 wherein the impurity comprises germanium.

24. The microelectronic device of claim 17 wherein the electrode impurity concentration ranges between about 1×10¹³ atoms/cm² and about 1×10¹⁹ atoms/cm².

25. The microelectronic device of claim 17 wherein the sill comprises silicon germanium.

26. The microelectronic device of claim 17 wherein the sill comprises strained silicon.

27. The microelectronic device of claim 17 wherein the second sill comprises diamond.

28. A microelectronic device, comprising:
a substrate including a plurality of doped regions;
a patterned feature located over the substrate, the patterned feature including at least one electrode, wherein the electrode is located over a channel region, the channel region located over an insulator located below the channel region and interposing at least two doped regions, the insulator comprised substantially of air; and
a sill located within the electrode, the sill including at least one monolayer of compound and adapted for modifying an electrical property of the channel region adjacent the electrode.

29. An integrated circuit device, comprising:
a substrate;
a plurality of microelectronic devices, each comprising:
a patterned feature located over the substrate and a plurality of doped regions, the patterned feature comprises at least one electrode, the electrode proximate a plurality of doped layers, and
a sill located within the electrode, the sill comprising at least one impurity and adapted for modifying an electrical property of at least one member adjacent the electrode; and
a plurality of interconnect layers for electrically interconnecting the plurality of microelectronic devices.

30. The integrated circuit device of claim 29 further comprising a second sill located below the first sill and proximate the electrode.

31. The integrated circuit of claim 30 wherein the first sill is removed to provide a silicon-on-nothing (SON) substrate, the SON substrate comprising the second sill, a dielectric layer, and the substrate.

32. The integrated circuit device of claim 29 wherein the substrate is diamond.

33. The integrated circuit device of claim 29 wherein the substrate is strained silicon.

34. The integrated circuit device of claim 29 wherein the substrate is strained silicon germanium.

35. The integrated circuit of claim 29 wherein the microelectronic device is a FinFET.

36. The integrated circuit of claim 35 wherein the electrode comprises at least one portion having the sill.

37. The integrated circuit of claim 35 wherein the sill substantially occupies the electrode, the sill occupying portions remote of a channel of the FinFET.

38. An integrated circuit device, comprising:
a substrate;
a plurality of microelectronic devices, each comprising:
a patterned feature located over the substrate, the patterned feature including at least one electrode, wherein the electrode is located over a channel region, the channel region located over an insulator located below the channel region and interposing at least two doped regions, the insulator comprised substantially of air, and
a sill located within the electrode, the sill including at least one monolayer of compound and adapted for modifying an electrical property of the channel region adjacent the electrode; and
a plurality of interconnect layers for electrically interconnecting the plurality of microelectronic devices.
